(19) United States
(12) Patent Application Publication
(10) Pub. No.: US 2025/0041959 A1
(43) Pub. Date: Feb. 6, 2025

(54) OPTIMIZATION OF THE DISTRIBUTION OF SPOT WELDS

(71) Applicant: Ford Global Technologies, LLC, Dearborn, MI (US)

(72) Inventor: Yafei Dong, Docklands (AU)

(73) Assignee: Ford Global Technologies, LLC, Dearborn, MI (US)

(21) Appl. No.: 18/365,691

(22) Filed: Aug. 4, 2023

(51) Int. Cl. B23K 9/095; B23K 11/11; B23K 31/12

(52) U.S. Cl. CPC B23K 9/0953; B23K 11/11; B23K 31/125; B23K 2101/006

(57) ABSTRACT

A method for welding components of a vehicle includes iteratively determining spot welds, generating a plurality of clusters of the spot welds, determining one or more centroid distances between the plurality of clusters, generating a spot weld model based on the one or more centroid distances, and welding the components of the vehicle based on the spot weld model.

### FIELD

The present disclosure relates to spot welding of components. More specifically, the present disclosure relates to spot welding of components with an optimal number of spot welds.

### BACKGROUND

The statements in this section merely provide background information related to the present disclosure and may not constitute prior art.

In many industries, for example, the automotive industry, welding is utilized to connect or join separate metal components. A particular form of welding employed in the automotive industry, as well as other industries, is spot welding. For example, to form the body of a structure portions of the body are formed by welding together numerous plates with several thousand spot weld points. The arrangement of the spot welds, that is, the spacing and location of the spot welds, is a significant factor that influences the rigidity and the strength of the body. Typically, the spacing and location of the spot welds is on experience and experimental tests.

Accordingly, without optimizing the spacing and number of spot welds in the formation of a vehicle body adds to the manufacturing cycle time.

These issues related to spot welding of components of a body are addressed by the present disclosure.

### SUMMARY

This section provides a general summary of the disclosure and is not a comprehensive disclosure of its full scope or all of its features.

In one form of the present disclosure, a method for welding components of a vehicle includes iteratively determining spot welds, generating a plurality of clusters of the spot welds, determining one or more centroid distances between the plurality of clusters, generating a spot weld model based on the one or more centroid distances, and welding the components of the vehicle based on the spot weld model.

In variations of this method, which may be implemented individually or in any combination: the selected spot welds are converted to spot weld lines; each spot line is a design variable; the spot welds are based on one or more constraints; a torsional stiffness of the vehicle is a constraint; structural integrity of a top of the vehicle is a constraint; structural integrity of an offset deformable barrier of the vehicle is a constraint; the spot welds define a dataset of base spot welds; a clustering analysis of the dataset of base spot welds is performed; the plurality of clusters of spot welds are identified from the dataset of base spot welds; and the spot welds are distributed non-uniformly on a component of the vehicle.

In another form, a method for welding components of a vehicle, the method includes defining spot weld design variables from a dataset of base spot welds, converting the spot weld design variables to spot weld line design variables, importing the spot weld line design variables to a vehicle load model, clustering spot welds based on output of the vehicle load model to generate a plurality of clusters of spot welds, and welding the components of the vehicle based on the plurality of clusters of spot welds.

In variations of this method, which may be implemented individually or in any combination: the method further includes minimizing a number of spot welds based on one or more constraints; a torsional stiffness of the vehicle is a constraint; structural integrity of a top of the vehicle is a constraint; structural integrity of an offset deformable barrier of the vehicle is a constraint; spot welds are distributed non-uniformly on a component of the vehicle; and the number of spot welds with clustering of the spot welds is less than a number of spot welds without clustering.

In yet another form, a method for welding components of a vehicle, includes iteratively determining spot welds, generating a plurality of clusters of the spot welds, determining one or more centroid distances between the plurality of clusters, generating a spot weld model based on the one or more centroid distances, and welding the components of the vehicle based on the spot weld model. A number of spot welds is minimized based on constraints including torsional stiffness of the vehicle, structural integrity of a top of the vehicle, and structural integrity of an offset deformable barrier of the vehicle.

In a variation of this method, a clustering analysis of the plurality of clusters of spot welds is performed.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 shows a panel for a vehicle with an arrangement of spot welds;

FIG. 2A shows base spot welds from the panel shown in FIG. 1 in accordance with the principles of the present disclosure;

FIG. 2B shows a conversion of the base spot welds shown in FIG. 2A into base spot lines in accordance with the principles of the present disclosure;

FIG. 3 shows an optimization scheme to reduce the number of spot welds in accordance with the principles of the present disclosure;

FIG. 4A shows results of a torsional strength constraint analysis of the spot welds in accordance with the principles of the present disclosure;

FIG. 4B shows the location of spot welds based on the torsional strength constraint analysis shown in FIG. 4A in accordance with the principles of the present disclosure;

FIG. 5A shows results of a structural integrity constraint analysis of the spot welds for a top of the vehicle in accordance with the principles of the present disclosure;

FIG. 5B shows the location of spot welds based on the structural integrity strength constraint analysis shown in FIG. 5A in accordance with the principles of the present disclosure;

FIG. 6A shows results of a structural integrity constraint analysis of an offset deformable barrier of the vehicle in accordance with the principles of the present disclosure;

FIG. 6B shows the location of spot welds based on the structural integrity strength constraint analysis shown in FIG. 5A in accordance with the principles of the present disclosure;

FIG. 7 shows the location of spot welds prior to a clustering analysis in accordance with the principles of the present disclosure;

FIG. 8A shows the location of five clusters of spot welds after the clustering analysis in accordance with the principles of the present disclosure;

FIG. 8B shows the location of twenty clusters of spot welds after the clustering analysis in accordance with the principles of the present disclosure;

FIG. 9 shows the optimized location and spacing of spot welds on the panel of the vehicle of spot welds after the clustering analysis in accordance with the principles of the present disclosure; and

FIG. 10 shows a flow diagram for a process to optimize the number of spot welds in accordance with the principles of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

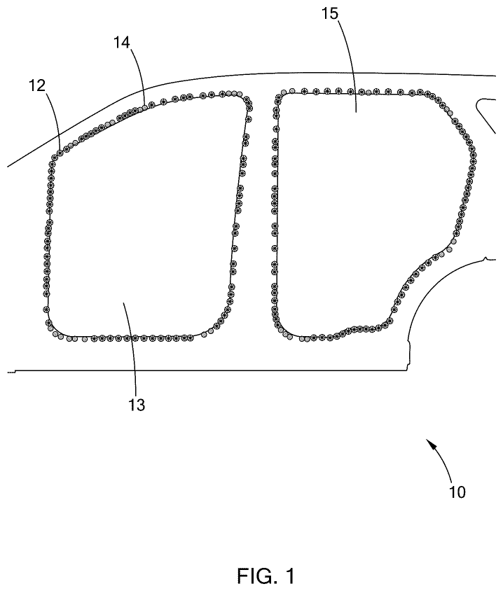

The present disclosure describes a method to optimize the location and spacing of spot welds, for example, on a panel 10 shown in FIG. 1. The term optimization refers to the minimization of the number of spot welds with optimal spacing between the spot welds, including non-uniform spacing. The panel 10 in some variations is a panel for a motor vehicle. The panel 10 includes a set of base spot welds 12 and 14 surrounding a pair of openings 13 and 15. Prior to the optimization of the placement of spot welds, the spot welds 12 represent spot welds that can be optimized, while the spot welds 14 represent spot welds that cannot be optimized because of certain design requirements of the panel 10. The method generates a case model that minimizes spot welds based on spot weld lines and performance constraints as a target.

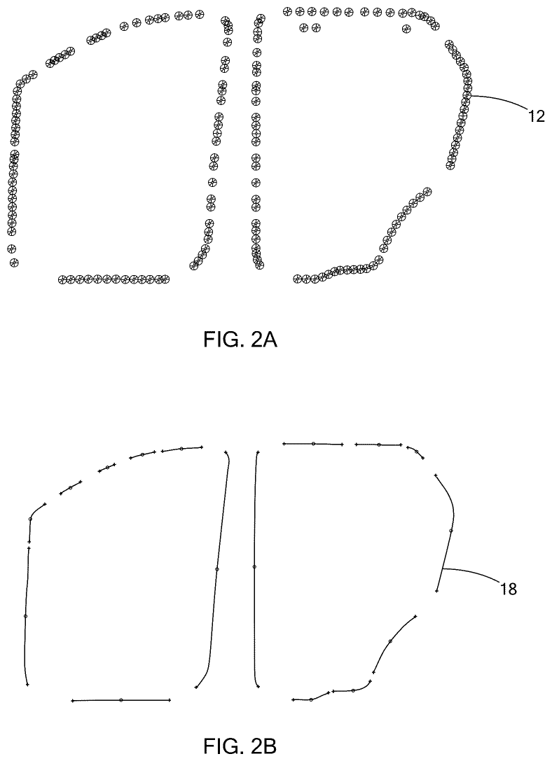

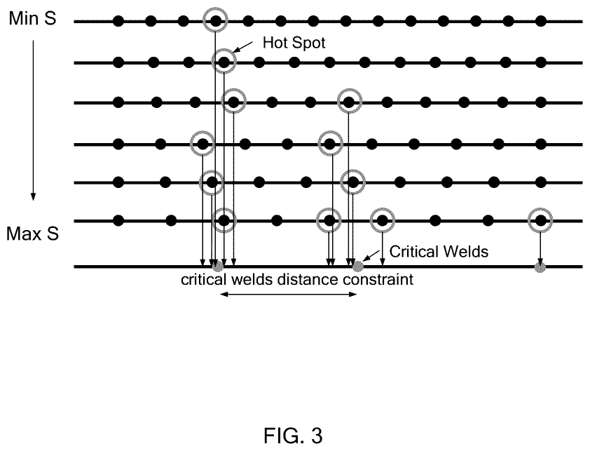

Referring to FIGS. 2A and 2B, the base spot welds 12 are converted to a set of base spot lines 18. And FIG. 3 illustrates the overview of the optimization process to obtain non-uniformly a spot weld layout from uniformly design of experiments. For each step of the process design of experiments, the process defines a group of spot welds layout from minimum spacing to maximum spacing to find the hot spots in a following step. After multiple steps or iterations, the process determines the hot spots to get a final non-uniformly spot weld layout design. Specifically, each spot weld line shown in FIG. 2B is a design variable that utilizes the design of experiments to define uniformly spaced spot welds as design variable for the subsequent step in the process.

The hot spots are identified that define a non-uniform distribution of critical welds. More specifically, the hot spots are constrained by the minimum spacing (Min S) and the maximum spacing (Max S) allowable between spot welds and are further constrained by distance between critical welds.

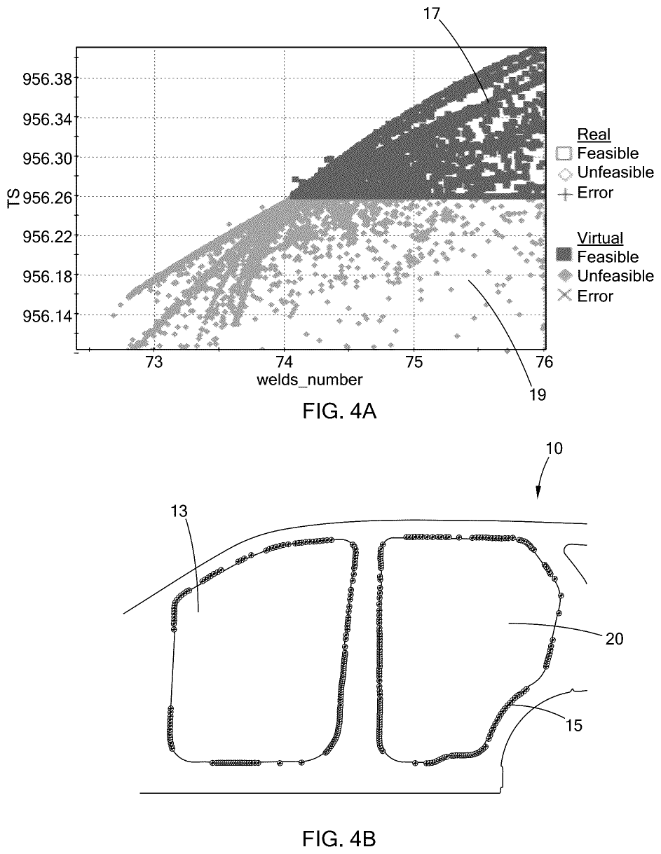

Next, as shown in FIGS. 4A and 4B, a structural constraint for the torsional stiffness of the panel 10 is applied to determine which spot welds are to be utilized to satisfy the constraint. Specifically, FIG. 4A shows a region 16 that satisfies the torsional stiffness requirement and a region 19 that does not satisfy the torsional stiffness requirement. At the boundary between the two regions 17 and 19, the minimum number of spot welds to satisfy the torsional stiffness constraint is 74 that are distributed as shown in FIG. 4B.

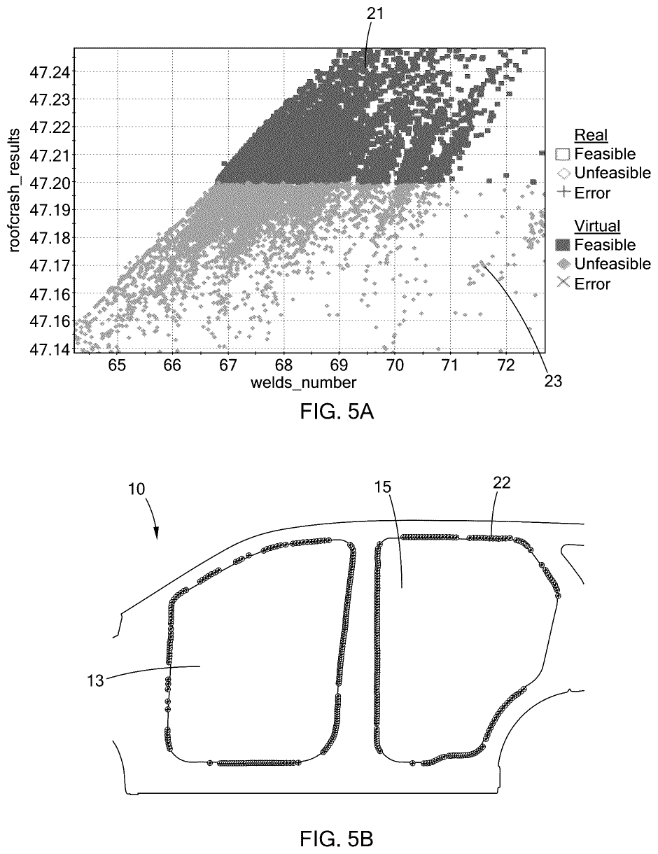

Turning further to FIGS. 5A and 5B, a structural constraint for the structural in integrity of a top of the vehicle associated with the panel 10 is applied to determine which spot welds are to be utilized to satisfy this constraint. Specifically, FIG. 5A shows a region 21 that satisfies the torsional stiffness requirement and a region 23 that does not satisfy the torsional stiffness requirement. At the boundary between the two regions 21 and 23, the minimum number of spot welds to satisfy the structural integrity of the top constraint is 67 that are distributed as shown in FIG. 5B.

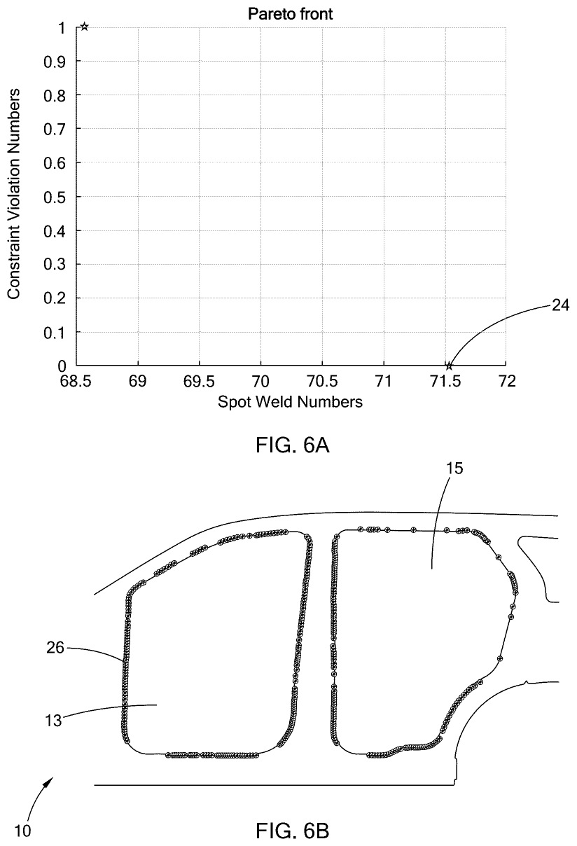

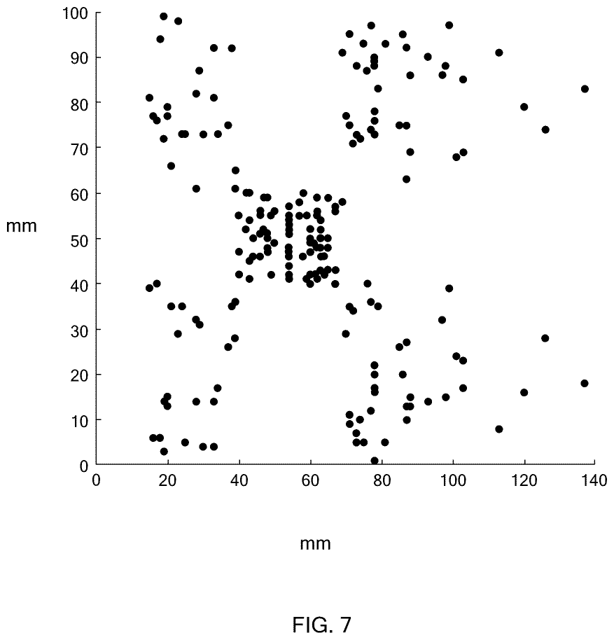

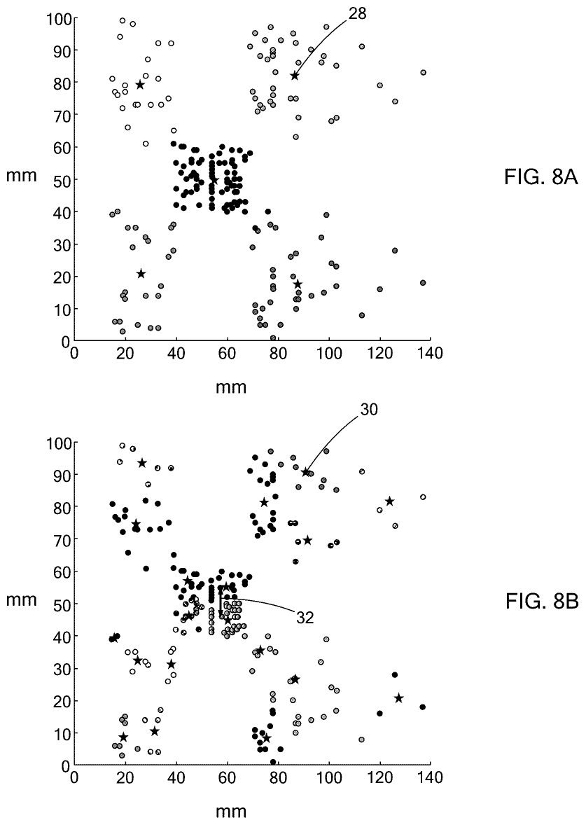

Another constraint is shown in FIGS. 6A and 6B, namely, a structural constraint for the structural in integrity of an offset deformable barrier (ODB) of the vehicle is applied to determine which spot welds are to be utilized to satisfy this constraint. Specifically, FIG. 6A shows the minimum number of spot welds to satisfy the structural constraint of the offset deformable barrier of the vehicle is 72 that are distributed as shown in FIG. 6B. Referring now to FIG. 7, a plot of the hot spot welds is shown positioned in space (X(mm) vs. Y(mm)). FIG. 8A shows the clustering of the data into five clusters identified by the stars 28. Further clustering of the data into 20 clusters identified by the stars 30 is shown in FIG. 8B. The distance between the centroids of the clusters 32 is also identified. Like FIG. 7, FIGS. 8A and 8B show the position of the hot spot welds in space (X(mm) vs. Y(mm)).

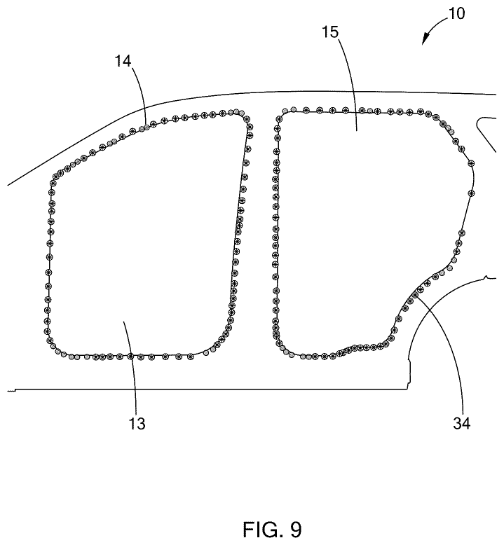

In a particular simulation, a base model with 161 spot welds 12 (FIG. 1) was reduced by the above-described optimization model to 130 spot welds 34 (FIG. 9). In this simulation, both the base model and the optimized model yielded a torsional stiffness of 956.3 KN m/rad, and both the base model and the optimized model resulted in a structural integrity of a top of 47.2 KN. For the ODB analysis, the base model provided a dash encroachment of 154.2 mm, while the optimized model resulted in a dash encroachment of 155.4 mm. Accordingly, the spot weld optimization process for designing the most efficient spot weld layout met the demands of the base spot welds.

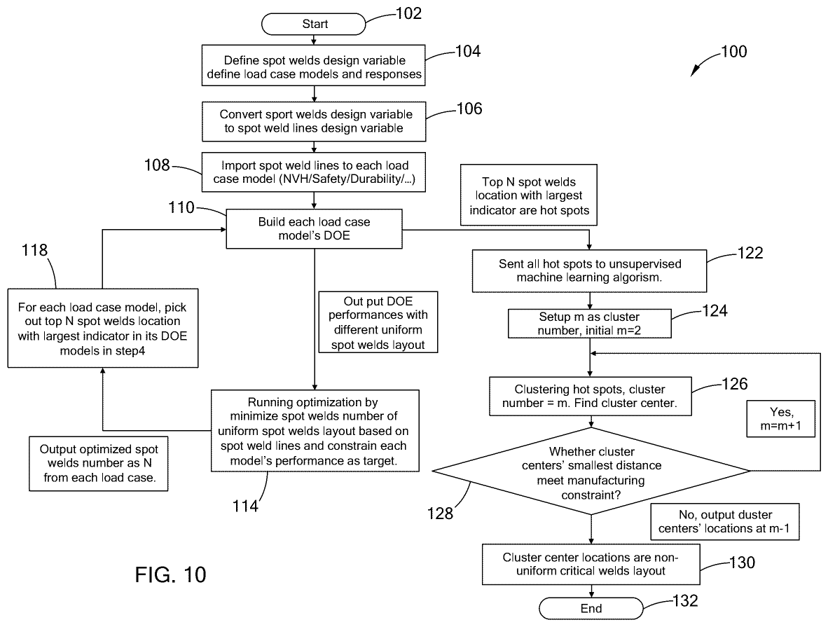

Referring now to FIG. 10, there is shown a process 100 that implements the optimization process described above. The process begins with a step 102 and proceeds to a step 104 where spot welds design variables are defined. A load case model and responses are defined as well. The load case model includes but is not limited to NVH and durability, and the responses include but are not limited to displacement, life, stress, strain, and permanent set. Next, in a step 106, the spot welds design variables are converted to spot weld lines design variables. This step parameterizes different uniformed spot welds layout in certain regions of, for example, the panel 10. Next, in a step 108, the process imports spot weld lines to each load case model to ensure the same design variables are utilized in different models.

Subsequently, in a step 110, each load case model is built so that the output response results of different uniform spot welds for a step 114 and to identify the top N spot weld locations with the largest indicator as hot spots for step 122. In the step 114, the minimal number of spot welds is optimized to provide the number of uniform spot welds layout based on spot weld lines and constraint of each model's performance as a target. The optimization is based on design of experiment results. Thus, the step 114 facilitates finding the minimum number of spot welds N that makes the performance meet target of each load case model.

Next, in a step 118, for each load case model, the top N spot weld locations with the largest indicator in its design of experiment models in the step 110 is identified as hot stops. Hence, the steps 114 and 118 balance different load case models optimization results, which make the process become an efficient multi-disciplinary design optimization for NVH and durability.

The step 118 sends information regarding the hot spots to an algorithm, such as, for example, a machined learning algorithm in a step 122 to draw inferences from datasets including input data without labeled responses. As such, hot spots are defined as clusters of datasets for non-uniform layout of the welds.

Next, in a step 124, the process 100 defines a cluster number as m with an initial m=2. Then, in a step 126, the hot spots are clustered based on the number=m, and the center of each cluster is determined.

In a decision step 128, the step determines whether the cluster centers' smallest distance meet a manufacturing constraint. If yes, m=m+1, and the process 100 returns to the step 126. If the decision step 128 determines that the answer is no, then the cluster centers are set to m−1. This step finds out the maximum number of clusters with meeting manufacturing constraint. Finally, in a step 130, the cluster center locations are identified as the non-uniform critical welds layout and the process 100 ends at a step 132.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The apparatuses and methods described in this application may be partially or fully implemented by a special purpose computer created by configuring a general-purpose computer to execute one or more particular functions embodied in computer programs. The functional blocks, flowchart components, and other elements described above serve as software specifications, which can be translated into the computer programs by the routine work of a skilled technician or programmer.

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A method for welding components of a vehicle, the method comprising:
iteratively determining spot welds;
generating a plurality of clusters of the spot welds;
determining one or more centroid distances between the plurality of clusters;
generating a spot weld model based on the one or more centroid distances; and
welding the components of the vehicle based on the spot weld model.

2. The method of claim 1, wherein selected spot welds are converted to spot weld lines.

3. The method of claim 2, wherein each spot line is a design variable.

4. The method of claim 1, wherein the spot welds are based on one or more constraints.

5. The method of claim 4, wherein a torsional stiffness of the vehicle is a constraint.

6. The method of claim 4, wherein structural integrity of a top of the vehicle is a constraint.

7. The method of claim 4, wherein structural integrity of an offset deformable barrier of the vehicle is a constraint.

8. The method of claim 1, wherein the spot welds define a dataset of base spot welds.

9. The method of claim 8, wherein a clustering analysis of the dataset of base spot welds is performed.

10. The method of claim 9, wherein the plurality of clusters of spot welds are identified from the dataset of base spot welds.

11. The method of claim 1, wherein the spot welds are distributed non-uniformly on a component of the vehicle.

12. A method for welding components of a vehicle, the method comprising:
defining spot weld design variables from a dataset of base spot welds;
converting the spot weld design variables to spot weld line design variables;
importing the spot weld line design variables to a vehicle load model;
clustering spot welds based on output of the vehicle load model to generate a plurality of clusters of spot welds; and
welding the components of the vehicle based on the plurality of clusters of spot welds.

13. The method of claim 12, further comprising minimizing a number of spot welds based on one or more constraints.

14. The method of claim 13, wherein a torsional stiffness of the vehicle is a constraint.

15. The method of claim 13, wherein structural integrity of a top of the vehicle is a constraint.

16. The method of claim 13, wherein structural integrity of an offset deformable barrier of the vehicle is a constraint.

17. The method of claim 12, wherein the spot welds are distributed non-uniformly on a component of the vehicle.

18. The method of claim 12, wherein a number of spot welds with clustering of the spot welds is less than the number of spot welds without clustering.

19. A method for welding components of a vehicle, the method comprising:
iteratively determining spot welds;
generating a plurality of clusters of the spot welds;
determining one or more centroid distances between the plurality of clusters;
generating a spot weld model based on the one or more centroid distances; and
welding the components of the vehicle based on the spot weld model,
wherein the number of spot welds is minimized based on constraints including torsional stiffness of the vehicle, structural integrity of a top of the vehicle, and structural integrity of an offset deformable barrier of the vehicle.

20. The method of claim 19, wherein a clustering analysis of the plurality of clusters of spot welds is performed.
